(19) United States
(12) Patent Application Publication
(10) Pub. No.: US 2024/0313130 A1
(43) Pub. Date: Sep. 19, 2024

(54) JUNCTION BARRIER SCHOTTKY DIODE

(71) Applicant: TDK Corporation, Tokyo (JP)

(72) Inventors: Jun ARIMA, Tokyo (JP); Minoru FUJITA, Tokyo (JP); Katsumi KAWASAKI, Tokyo (JP); Jun HIRABAYASHI, Tokyo (JP)

(21) Appl. No.: 18/676,107

(22) Filed: May 28, 2024

Related U.S. Application Data
(63) Continuation of application No. PCT/JP2022/030766, filed on Aug. 12, 2022.

(30) Foreign Application Priority Data
Nov. 29, 2021 (JP) 2021-193060

(51) Int. Cl. H01L 29/872; H01L 29/47

(52) U.S. Cl. CPC H01L 29/8725; H01L 29/47

(57) ABSTRACT

Disclosed herein is a junction barrier Schottky diode includes a semiconductor substrate made of gallium oxide, a drift layer made of gallium oxide and provided on the semiconductor substrate, an anode electrode brought into Schottky contact with the drift layer, and a cathode electrode brought into ohmic contact with the semiconductor substrate. The drift layer has a center trench filled with the anode electrode and a semiconductor material having a conductivity type opposite to that of the drift layer. A bottom surface of the center trench contacts the semiconductor material without being in contact with the anode electrode. At least a part of a side surface of the center trench is brought into Schottky contact with the anode electrode.

### CROSS-REFERENCE OF RELATED APPLICATIONS

This application is a Continuation of International Patent Application No. PCT/JP2022/030766, filed on Aug. 12, 2022, which in turn claims the benefit of Japanese Patent Application No. 2021-193060, filed on Nov. 29, 2021, the entire disclosure of which Applications are incorporated by reference herein.

### BACKGROUND OF THE ART

The present disclosure relates to a junction barrier Schottky diode and, more particularly, to a junction barrier Schottky diode using gallium oxide.

A Schottky barrier diode is a rectifying element utilizing a Schottky barrier generated due to bonding between metal and a semiconductor and is lower in forward voltage and higher in switching speed than a normal diode having a PN junction. Thus, the Schottky barrier diode is sometimes utilized as a switching element for a power device.

When the Schottky barrier diode is utilized as a switching element for a power device, it is necessary to ensure a sufficient backward withstand voltage, so that silicon carbide (Sic), gallium nitride (GaN), or gallium oxide (Ga₂O₃) having a larger band gap is sometimes used in place of silicon (Si). Among them, gallium oxide has a very large band gap (4.8 eV to 4.9 eV) and a large breakdown field of about 8 MV/cm, so that a Schottky barrier diode using gallium oxide is very promising as the switching element for a power device. An example of the Schottky barrier diode using gallium oxide is described in JP 2019-036593 A.

JP 2019-036593 A discloses a junction barrier Schottky diode having a structure in which a plurality of trenches provided in a gallium oxide layer are filled with a p-type semiconductor material. By thus providing a plurality of trenches in the gallium oxide layer and filling the plurality of trenches with a p-type semiconductor material, a mesa region positioned between the trenches becomes a depletion layer upon application of a backward voltage, so that a channel region of a drift layer is pinched off. Thus, a leak current upon application of the backward voltage can be significantly reduced.

However, in the junction barrier Schottky diode described in JP 2019-036593 A, Schottky key contact area between an anode electrode and a drift layer is small, thus disadvantageously increasing ON-resistance of the Schottky diode. To reduce the ON-resistance, the impurity concentration of the drift layer should be increased; however, this reduces a backward withstand voltage.

### SUMMARY

It is desirable to provide a junction barrier Schottky diode using a gallium oxide, capable of reducing the ON-resistance while ensuring a sufficient backward withstand voltage.

A junction barrier Schottky diode according to the present disclosure includes: a semiconductor substrate made of gallium oxide; a drift layer made of gallium oxide and provided on the semiconductor substrate; an anode electrode brought into Schottky contact with the drift layer; and a cathode electrode brought into ohmic contact with the semiconductor substrate. The drift layer has a center trench filled with the anode electrode and a semiconductor material having a conductivity type opposite to that of the drift layer. A bottom surface of the center trench contacts the semiconductor material without being in contact with the anode electrode. At least a part of a side surface of the center trench is brought into Schottky contact with the anode electrode.

### BRIEF DESCRIPTION OF THE DRAWINGS

FIG. 1A is a schematic plan view illustrating the configuration of a junction barrier Schottky diode 1 according to a first embodiment of the present disclosure. FIG. 1B is a schematic cross-sectional view taken along the line A-A in FIG. 1A.

FIGS. 2A to 2C are schematic cross-sectional views for explaining the positions of the inner walls of the center trench 61 and the outer trench 62 that are covered with the p-type semiconductor material 80.

FIG. 3 schematic is a cross-sectional view illustrating the configuration of a junction barrier Schottky diode 2 according to a second embodiment of the present disclosure.

FIG. 4 is a schematic cross-sectional view illustrating the configuration of a junction barrier Schottky diode 3 according to a third embodiment of the present disclosure.

FIG. 5 is a schematic cross-sectional view illustrating the configuration of a junction barrier Schottky diode 4 according to a fourth embodiment of the present disclosure.

FIG. 6 is a schematic cross-sectional view illustrating the configuration of a junction barrier Schottky diode 5 according to a fifth embodiment of the present disclosure.

FIG. 7 is a schematic cross-sectional view illustrating the configuration of a junction barrier Schottky diode 6 according to a sixth embodiment of the present disclosure.

FIG. 8A is a schematic plan view illustrating the configuration of a junction barrier Schottky diode 7 according to a seventh embodiment of the present disclosure. FIG. 8B is a schematic cross-sectional view taken along the line A-A in FIG. 8A.

FIG. 9 is a schematic cross-sectional view illustrating the configuration of a junction barrier Schottky diode 8 according to an eighth embodiment of the present disclosure.

FIG. 10 is a schematic cross-sectional view illustrating the configuration of a junction barrier Schottky diode 9 according to a ninth embodiment of the present disclosure.

FIG. 11 is a schematic cross-sectional view illustrating the configuration of a junction barrier Schottky diode 10 according to a tenth embodiment of the present disclosure.

FIG. 12 is a schematic cross-sectional view illustrating the configuration of a junction barrier Schottky diode 11 according to an eleventh embodiment of the present disclosure.

FIG. 13A is a schematic plan view illustrating the configuration of a junction barrier Schottky diode 12 according to a twelfth embodiment of the present disclosure. FIG. 13B is a schematic cross-sectional view taken along the line A-A in FIG. 13A.

FIG. 14A is a schematic plan view illustrating the configuration of a junction barrier Schottky diode 13 according to a thirteenth embodiment of the present disclosure. FIG. 14B is a schematic cross-sectional view taken along the line A-A in FIG. 14A.

FIG. 15A is a schematic plan view illustrating the configuration of a junction barrier Schottky diode 14 according to a fourteenth embodiment of the present disclosure. FIG. 15B is a schematic cross-sectional view taken along the line A-A in FIG. 15A.

FIG. 16 is a schematic cross-sectional view illustrating the configuration of a junction barrier Schottky diode 15 according to a fifteenth embodiment of the present disclosure.

FIG. 17 is a graph showing the simulation results of the examples.

### DETAILED DESCRIPTION OF THE EMBODIMENTS

Hereinafter, embodiments of the present disclosure will be described in detail with reference to the accompanying drawings.

### First Embodiment

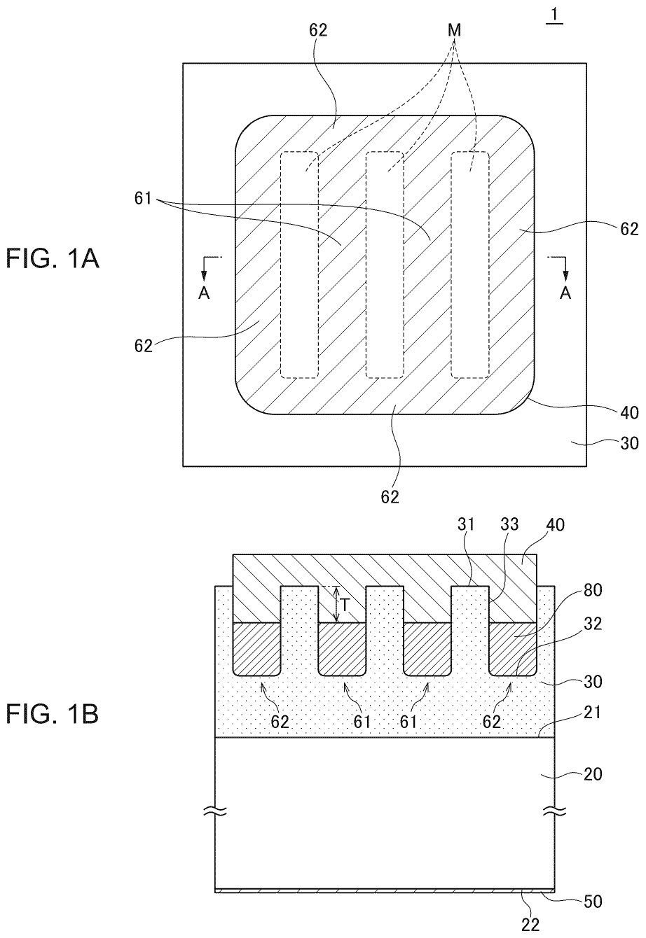

FIG. 1A is a schematic plan view illustrating the configuration of a junction barrier Schottky diode 1 according to a first embodiment of the present disclosure. FIG. 1B is a schematic cross-sectional view taken along the line A-A in FIG. 1A.

As illustrated in FIGS. 1A and 1B, the junction barrier Schottky diode 1 according to the first embodiment has a semiconductor substrate 20 and a drift layer 30, both of which are made of gallium oxide (β-Ga₂O₃). The semiconductor substrate 20 and drift layer 30 are each introduced with silicon (Si) or tin (Sn) as an n-type dopant. The concentration of the dopant is higher in the semiconductor substrate 20 than in the drift layer 30, whereby the semiconductor substrate 20 and the drift layer 30 function as an n⁺ layer and an n⁻ layer, respectively.

The semiconductor substrate 20 is obtained by cutting a bulk crystal formed using a melt-growing method and has a thickness of about 250 μm. The planar size of the semiconductor substrate 20 is not particularly limited and is generally selected in accordance with the amount of current flowing in the element. For example, when the maximum amount of forward current is about 20 A, the planar size may be set to about 2.4 mm×2.4 mm.

The semiconductor substrate 20 has an upper surface 21 positioned on the upper surface side in a mounted state and a back surface 22 positioned opposite the upper surface 21, on the lower surface side in a mounted state. The drift layer 30 is formed on the entire upper surface 21. The drift layer 30 is a thin film obtained by epitaxially growing gallium oxide on the upper surface 21 of the semiconductor substrate 20 using a reactive sputtering method, a PLD method, an MBE method, an MOCVD method, or an HVPE method. The film thickness of the drift layer 30 is not particularly limited and is generally selected in accordance with the backward withstand voltage of the element. For example, in order to ensure a withstand voltage of about 600V, the film thickness may be set to about 7 μm.

There is formed, on an upper surface 31 of the drift layer 30, an anode electrode 40 which is brought into Schottky contact with the drift layer 30. The anode electrode 40 is formed of metal such as platinum (Pt), palladium (Pd), gold (Au), nickel (Ni), molybdenum (Mo), or Copper (Cu). The anode electrode 40 may have a multilayer structure of different metal films, such as Pt/Au, Pt/Al, Pd/Au, Pd/Al, Pt/Ti/Au, or Pd/Ti/Au. On the other hand, there is formed, on the back surface 22 of the semiconductor substrate 20, a cathode electrode 50 which is brought into ohmic contact with the semiconductor substrate 20. The cathode electrode 50 is formed of metal such as titanium (Ti). The cathode electrode 50 may have a multilayer structure of different metal films, such as Ti/Au or Ti/Al.

In the present embodiment, a center trench 61 and an outer peripheral trench 62 are formed in the drift layer 30. The center and outer peripheral trenches 61 and 62 are each formed at a position overlapping the anode electrode 40 in a plan view and are each filled with the same metal material as the anode electrode 40 and a p-type semiconductor material 80. The P-type semiconductor material 80 is in contact with the anode electrode 40. Examples of the p-type semiconductor material 80 include Si, GaAs, GaN, SiC, Ge, ZnSe, CdS, InP, SiGe, AlN, BN, AlGAN, NiO, Cu₂O, Ir₂O₃, Ag₂O. Among them, a p-type oxide semiconductor, such as NiO, is free from oxidation problems. The center trench 61 is sandwiched between a mesa region M constituting a part of the drift layer 30. The outer peripheral trench 62 surrounds the mesa region M and center trench 61 in a ring. The center and outer peripheral trenches 61 and 62 need not be completely separated from each other, but may be connected to each other as illustrated in FIG. 1A. The depths of the center and outer peripheral trenches 61 and 62 may be the same or different. The mesa region M constitutes a part of the drift layer 30 that is partitioned by the center and outer peripheral trenches 61 and 62 and becomes a depletion layer when a backward voltage is applied between the anode and cathode electrodes 40 and 50. Thus, a channel region of the drift layer 30 is pinched off, so that a leak current upon application of the backward voltage is significantly reduced.

The center and outer peripheral trenches 61 and 62 are filled at their bottom with the p-type semiconductor material 80 and at their upper portion with the anode electrode 40. Accordingly, the bottom surface 32 and the lower portion of the side surface 33 constituting the inner wall of each of the center and outer peripheral trenches 61 and 62 contact the p-type semiconductor material 80, while the upper portion of the side surface 33 constituting the inner wall of each of the center and outer peripheral trenches 61 and 62 contacts the anode electrode 40. Thus, the drift layer 30 and anode electrode 40 are brought into Schottky contact not only at the upper surface 31 of the drift layer 30 but also at the upper portion of the side surface 33 of each of the center and outer peripheral trenches 61 and 62. This reduces ON-resistanace of the Schottky diode as compared with when the center and outer peripheral trenches 61 and 62 are entirely filled with the p-type semiconductor material 80. Further, the dopant concentration of the drift layer 30 can be reduced to about 3×10¹⁶ cm⁻³, thus preventing a reduction in backward withstand voltage.

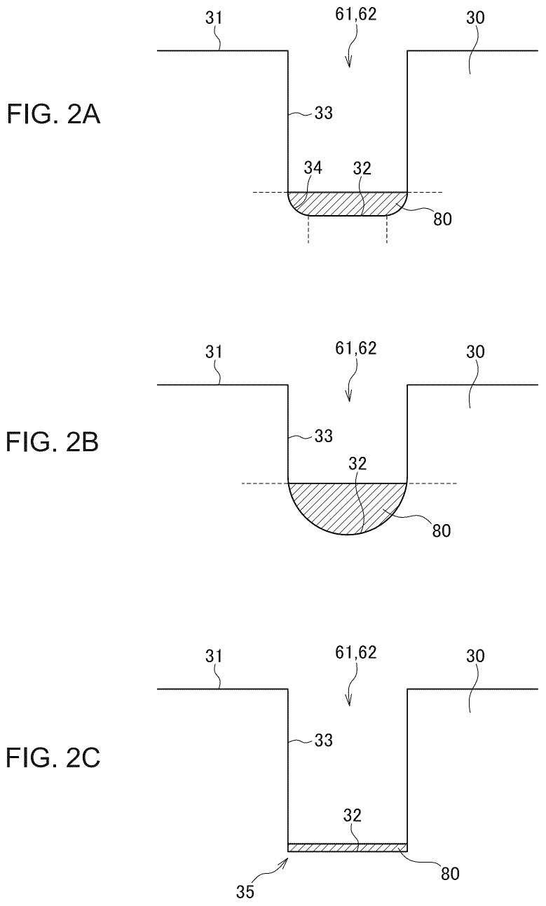

As illustrated in FIG. 2A, when the bottom surface 32 of each of the center and outer peripheral trenches 61 and 62 is horizontal, and a portion between the horizontal bottom surface 32 and the vertical side surface 33 is a curved surface 34, the bottom surface 32 and the curved surface 34 need to be covered with the p-type semiconductor material 80. Further, as illustrated in FIG. 2B, when the bottom surface 32 of each of the center and outer peripheral 61 and 62 is entirely curved, the entire curved bottom surface 32 needs to be covered with the p-type semiconductor material 80. Furthermore, as illustrated in FIG. 2C, when the bottom surface 32 of each of the center and outer peripheral trenches 61 and 62 is horizontal, and a right-angled corner portion 35 exists between the horizontal bottom surface 32 and vertical side surface 33, the bottom surface 32 and the corner portion 35 need to be covered with the p-type semiconductor material 80.

As described above, in the junction barrier Schottky diode 1 according to the present embodiment, the anode electrode 40 is brought into Schottky contact with the upper portion of the side surface 33 of each of the center and outer peripheral trenches 61 and 62, thereby making it possible to reduce the ON-resistance as compared with when the center and outer peripheral trenches 61 and 62 are entirely filled with the p-type semiconductor material 80.

### Second Embodiment

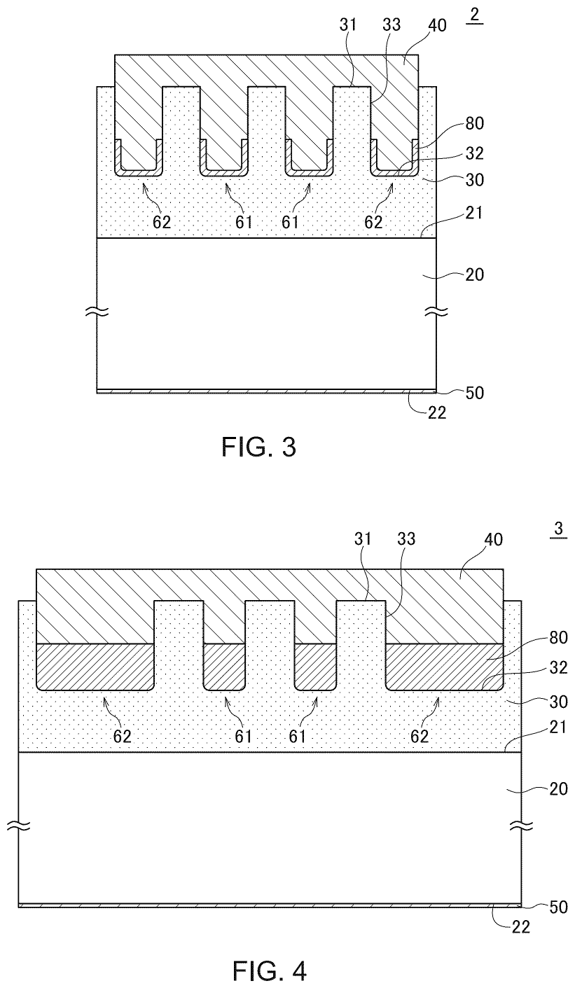

FIG. 3 is a schematic cross-sectional view illustrating the configuration of a junction barrier Schottky diode 2 according to a second embodiment of the present disclosure.

As illustrated in FIG. 3, the junction barrier Schottky diode 2 according to the second embodiment differs from the junction barrier Schottky diode 1 according to the first embodiment in that the p-type semiconductor material 80 covering the bottom surface 32 and the lower portion of the side surface 33 of each of the center and outer peripheral trenches 61 and 62 has a small film thickness, with the result that the anode electrode 40 is present also at the bottom portion of each of the center and outer peripheral trenches 61 and 62. Other basic configurations are the same as those of the junction barrier Schottky diode 1 according to the first embodiment, reference numerals are given to the same so the same elements, and overlapping description will be omitted. As in the present embodiment, the p-type semiconductor material 80 need not be filled in the entire bottom surface of each of the center and outer peripheral trenches 61 and 62 but may cover only the surface thereof.

### Third Embodiment

FIG. 4 is a schematic cross-sectional view illustrating the configuration of a junction barrier Schottky diode 3 according to a third embodiment of the present disclosure.

As illustrated in FIG. 4, the junction barrier Schottky diode 3 according to the third embodiment differs from the junction barrier Schottky diode 1 according to the first embodiment in that the width of the outer peripheral trench 62 is made larger in width than the center trench 61. Other basic configurations are the same as those of the junction barrier Schottky diode 1 according to the first embodiment, so the same reference numerals are given to the same elements, and overlapping description will be omitted. By thus increasing the width of the outer peripheral trench 62, it is possible to relax the electric field concentration in the vicinity of the bottom portion of the outer peripheral trench 62 upon application of a backward voltage.

### Fourth Embodiment

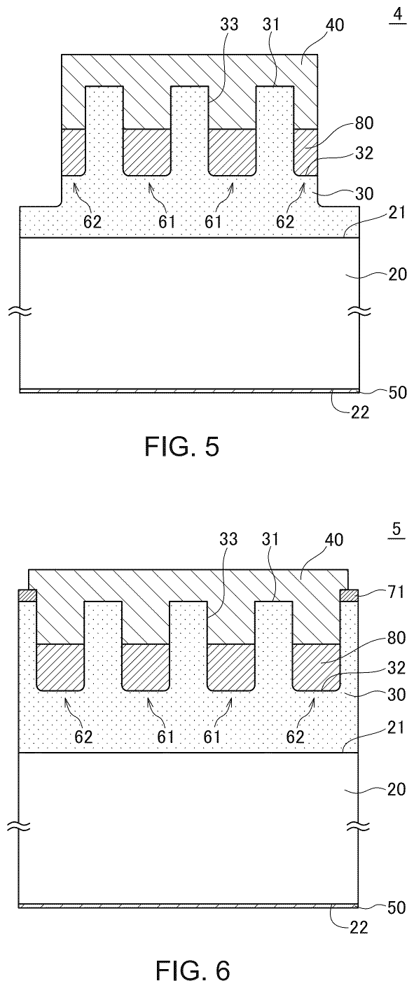

FIG. 5 is a schematic cross-sectional view illustrating the configuration of a junction barrier Schottky diode 4 according to a fourth embodiment of the present disclosure.

As illustrated in FIG. 5, the junction barrier Schottky diode 4 according to the fourth embodiment differs from the junction barrier Schottky diode 1 according to the first embodiment in that a part of the drift layer 30 that is positioned outside the outer peripheral trench 62 is removed. Other basic configurations are the same as those of the junction barrier Schottky diode 1 according to the first embodiment, so the same reference numerals are given to the same elements, and overlapping description will be omitted. An On-current hardly flows in the part of the drift layer 30 that is positioned outside the outer peripheral trench 62, so that the drift layer 30 may be removed at this position as in the present embodiment.

### Fifth Embodiment

FIG. 6 is a schematic cross-sectional view illustrating the configuration of a junction barrier Schottky diode 5 according to a fifth embodiment of the present disclosure.

As illustrated in FIG. 6, the junction barrier Schottky diode 5 according to the fifth embodiment differs from the junction barrier Schottky diode 1 according to the first embodiment in that an insulating film 71 is provided between the upper surface 31 of the part of the drift layer 30 that is positioned outside the outer peripheral trench 62 and the anode electrode 40. Other basic configurations are the same as those of the junction barrier Schottky diode 1 according to the first embodiment, so the same reference numerals are given to the same elements, and overlapping description will be omitted. The material of the insulating film 71 may be a material having a high withstand voltage, such as SiO₂ or Al₂O₃. This improves withstand voltage effect. According to the present embodiment, a so-called field plate structure is achieved by the presence of the insulating film 71, allowing more relaxation of an electric field to be applied to the bottom portion of the outer peripheral trench 62.

### Sixth Embodiment

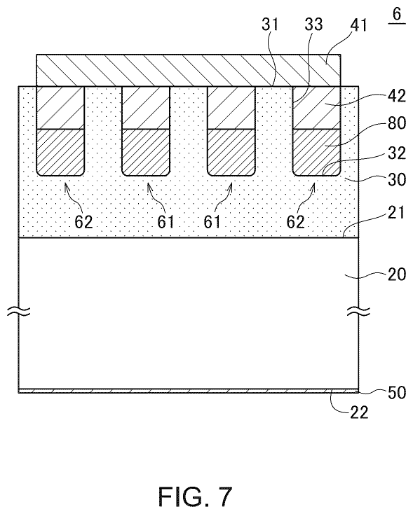

FIG. 7 is a schematic cross-sectional view illustrating the configuration of a junction barrier Schottky diode 6 according to a sixth embodiment of the present disclosure.

As illustrated in FIG. 7, the junction barrier Schottky diode 6 according to the sixth embodiment differs from the junction barrier Schottky diode 1 according to the first embodiment in that an anode electrode 41 covering the upper surface of the drift layer 30 and an anode electrode 42 filled in the center and outer peripheral trenches 61 and 62 are made of mutually different metal materials. Other basic configurations are the same as those of the junction barrier Schottky diode 1 according to the first embodiment, so the same reference numerals are given to the same elements, and overlapping description will be omitted. Such a structure can be obtained by, for example, forming the anode electrode 42 and the anode electrode 41 by electrolytic plating and vapor deposition, respectively. Such a manufacturing method makes it hard to generate a void in the anode electrode 42 filled in the center and outer peripheral trenches 61 and 62.

### Seventh Embodiment

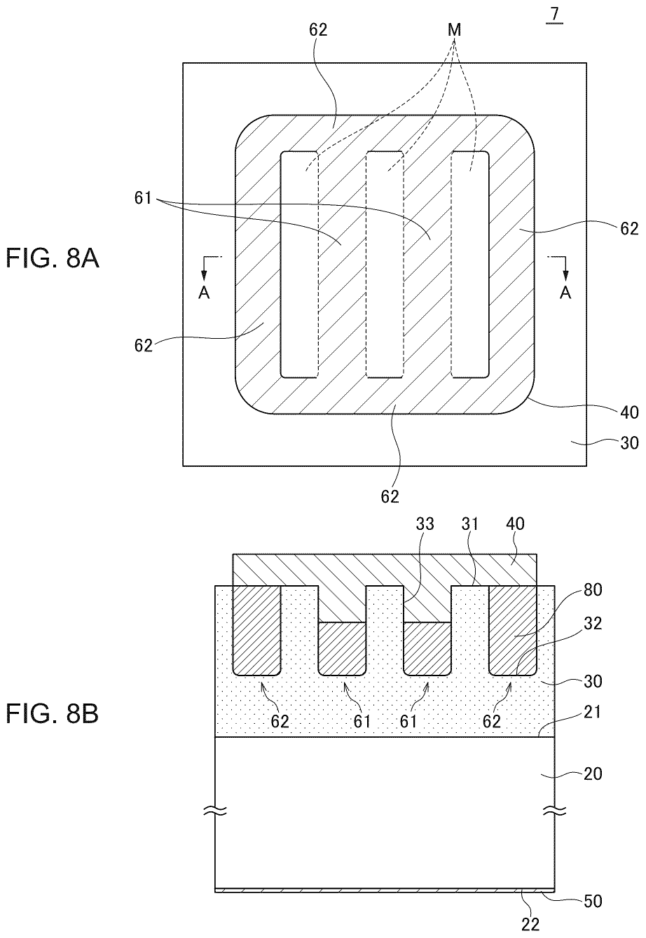

FIG. 8A is a schematic plan view illustrating the configuration of a junction barrier Schottky diode 7 according to a seventh embodiment of the present disclosure. FIG. 8B is a schematic cross-sectional view taken along the line A-A in FIG. 8A.

As illustrated in FIGS. 8A and 8B, the junction barrier Schottky diode 7 according to the seventh embodiment differs from the junction barrier Schottky diode 1 according to the first embodiment in that the entire outer peripheral trench 62 is filled with the p-type semiconductor material 80. Other basic configurations are the same as those of the junction barrier Schottky diode 1 according to the first embodiment, so the same reference numerals are given to the same elements, and overlapping description will be omitted. In FIG. 8A, a part of the surface of the mesa region M that is brought into Schottky contact with the drift layer 30 is denoted by a dashed line, while a part of the surface of the mesa region M that is covered with the p-type semiconductor material 80 is denoted by a solid line. This can further increase the backward withstand voltage.

### Eighth Embodiment

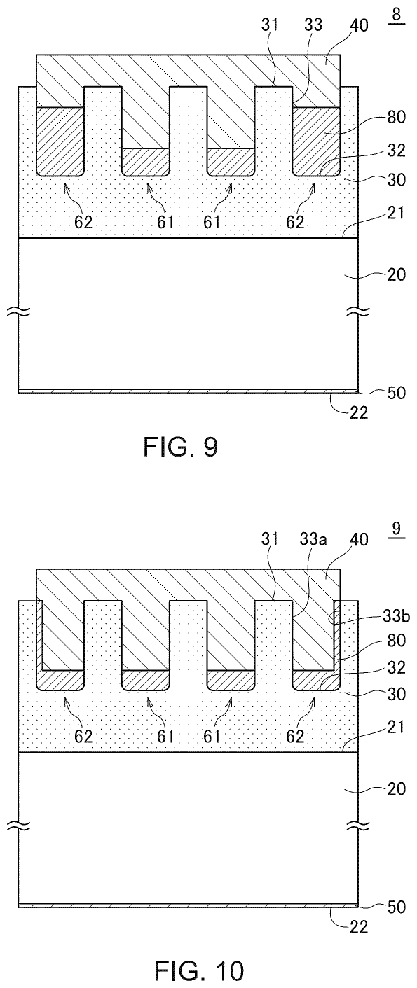

FIG. 9 is a schematic cross-sectional view illustrating the configuration of a junction barrier Schottky diode 8 according to an eighth embodiment of the present disclosure.

As illustrated in FIG. 9, the junction barrier Schottky diode 8 according to the eighth embodiment differs from the junction barrier Schottky diode 7 according to the seventh embodiment in that the height position of the p-type semiconductor material 80 filled in the outer peripheral trench 62 is lower than that in the junction barrier Schottky diode 7 according to the seventh embodiment to thereby bring a part of the side surface 33 of the outer peripheral trench 62 into Schottky contact with the anode electrode 40. Other basic configurations are the same as those of the junction barrier Schottky diode 7 according to the seventh embodiment, so the same reference numerals are given to the same elements, and overlapping description will be omitted. According to the present embodiment, the ON-resistance can be reduced more than that in the junction barrier Schottky diode 7 according to the seventh embodiment while the backward withstand voltage is increased.

### Ninth Embodiment

FIG. 10 is a schematic cross-sectional view illustrating the configuration of a junction barrier Schottky diode 9 according to a ninth embodiment of the present disclosure.

As illustrated in FIG. 10, the junction barrier Schottky diode 9 according to the ninth embodiment differs from the junction barrier Schottky diode 7 according to the seventh embodiment in that a part of the p-type semiconductor material 80 that contacts an inner side surface 33a constituting the inner side of the side surface 33 of the outer peripheral trench 62 is replaced by the anode electrode 40. An outer side surface 33b constituting the outer side of the side surface 33 of the outer peripheral trench 62 is entirely covered with the p-type semiconductor material 80. Other basic configurations are the same as those of the junction barrier Schottky diode 7 according to the seventh embodiment, so the same reference numerals are given to the same elements, and overlapping description will be omitted. In the present embodiment as well, the ON-resistance can be reduced more than that in the junction barrier Schottky diode 7 according to the seventh embodiment while the backward withstand voltage is increased.

### Tenth Embodiment

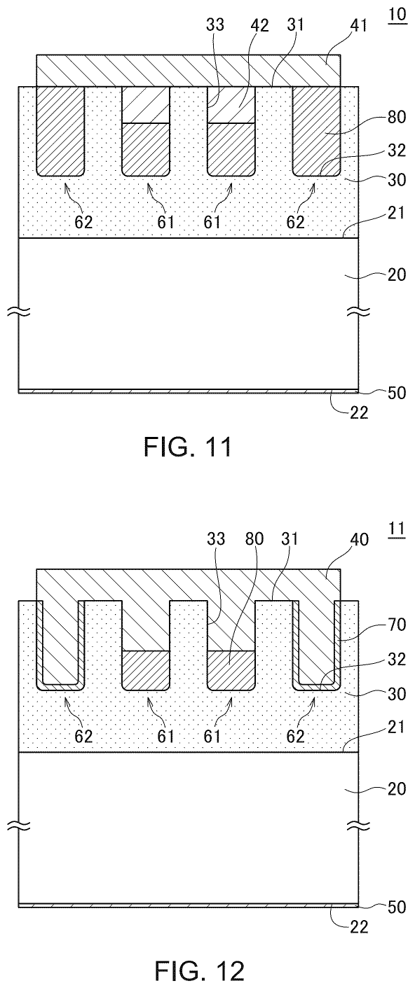

FIG. 11 is a schematic cross-sectional view illustrating the configuration of a junction barrier Schottky diode 10 according to a tenth embodiment of the present disclosure.

As illustrated in FIG. 11, the junction barrier Schottky diode 10 according to the tenth embodiment differs from the junction barrier Schottky diode 7 according to the seventh embodiment in that the anode electrode 41 covering the upper surface of the drift layer 30 and the anode electrode 42 filled in the center trench 61 are made of mutually different metal materials. Other basic configurations are the same as those of the junction barrier Schottky diode 7 according to the seventh embodiment, so the same reference numerals are given to the same elements, and overlapping description will be omitted. Such a structure can be obtained by, for example, forming the anode electrode 42 and the anode electrode 41 by electrolytic plating and vapor deposition, respectively. Such a manufacturing method makes it hard to generate a void in the anode electrode 42 filled in the center and outer peripheral trenches 61 and 62.

### Eleventh Embodiment

FIG. 12 is a schematic cross-sectional view illustrating the configuration of a junction barrier Schottky diode 11 according to an eleventh embodiment of the present disclosure.

As illustrated in FIG. 12, the junction barrier Schottky diode 11 according to the eleventh embodiment differs from the junction barrier Schottky diode 7 according to the seventh embodiment in that the inner wall of the outer peripheral trench 62 is covered with an insulating film 70 and that the outer peripheral trench 62 is filled with the anode electrode 40 with the insulating film 70 interposed therebetween. Other basic configurations are the same as those of the junction barrier Schottky diode 7 according to the seventh embodiment, so the same reference numerals are given to the same elements, and overlapping description will be omitted. In the present embodiment as well, the backward withstand voltage can be further increased as in the seventh embodiment. The material of the insulating film 70 may be an insulating material having a high dielectric constant, such as HfO₂ or Al₂O₃. This improves withstand voltage effect.

### Twelfth Embodiment

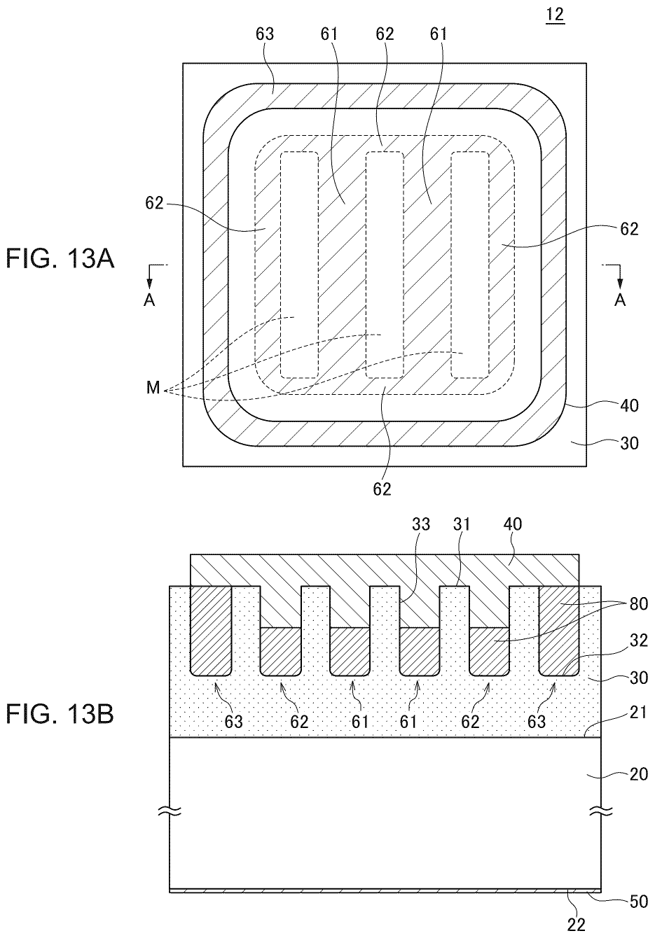

FIG. 13A is a schematic plan view illustrating the configuration of a junction barrier Schottky diode 12 according to a twelfth embodiment of the present disclosure. FIG. 13B is a schematic cross-sectional view taken along the line A-A in FIG. 13A.

As illustrated in FIGS. 13A and 13B, the junction barrier Schottky diode 12 according to the twelfth embodiment differs from the junction barrier Schottky diode 1 according to the first embodiment in that another outer peripheral trench 63 surrounding the outer peripheral trench 62 is provided in the drift layer 30 and that the entire outer peripheral trench 63 is filled with the p-type semiconductor material 80. The outer peripheral trench 63 is formed independently of the outer peripheral trench 62. Other basic configurations are the same as those of the junction barrier Schottky diode 1 according to the first embodiment, so the same reference numerals are given to the same elements, and overlapping description will be omitted. In FIG. 13A, a part of the surface of mesa region M that is brought into Schottky contact with the drift layer 30 is denoted by a dashed line, while a part of the surface of the mesa region M that is covered with the p-type semiconductor material 80 is denoted by a solid line. By thus providing the outer peripheral trench 63 different from the outer peripheral trench 62 in the drift layer 30 and filling the entire inner part thereof with the p-type semiconductor material 80, it is possible to relax the electric field concentration in the vicinity of the bottom portion of the center and outer peripheral trenches 61 and 62 upon application of a backward voltage.

### Thirteenth Embodiment

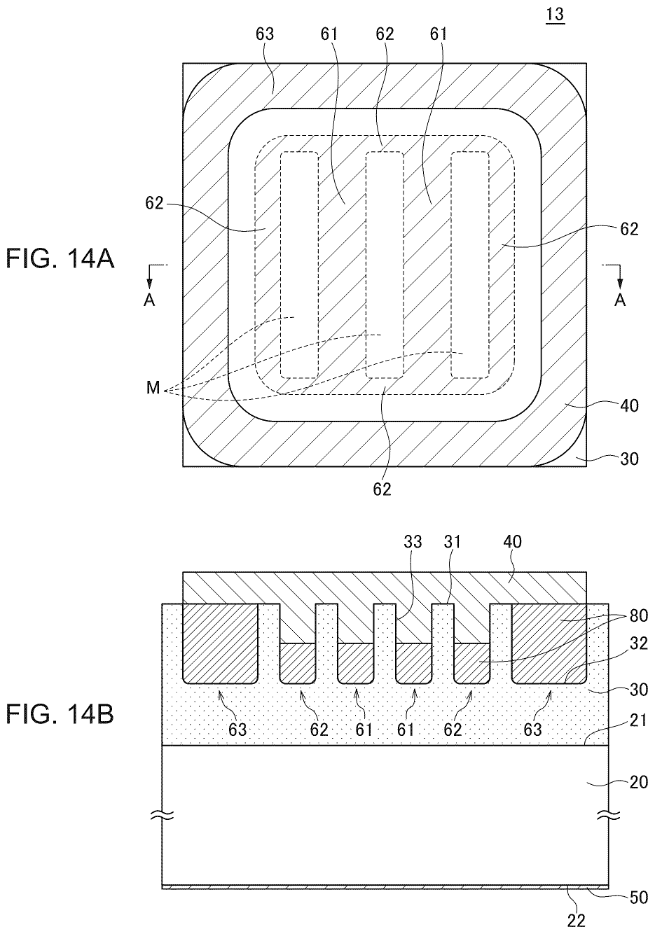

FIG. 14A is a schematic plan view illustrating the configuration of a junction barrier Schottky diode 13 according to a thirteenth embodiment of the present disclosure. FIG. 14B is a schematic cross-sectional view taken along the line A-A in FIG. 14A.

As illustrated in FIGS. 14A and 14B, the junction barrier Schottky diode 13 according to the thirteenth embodiment differs from the junction barrier Schottky diode 12 according to the twelfth embodiment in that the outer peripheral trench 63 is made larger in width than the center and outer peripheral trenches 61 and 62. Other basic configurations are the same as those of the junction barrier Schottky diode 12 according to the twelfth embodiment, so the same reference numerals are given to the same elements, and overlapping description will be omitted. By thus increasing the width of the outer peripheral trench 63, it is possible to relax the electric field concentration in the vicinity of the bottom portion of the outer peripheral trench 63 upon application of a backward voltage.

### Fourteenth Embodiment

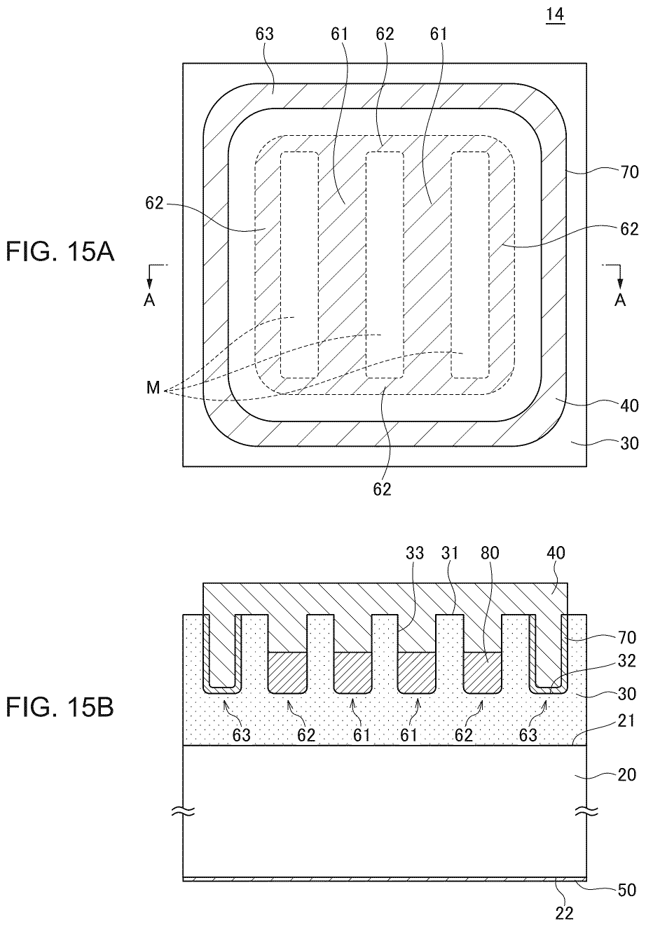

FIG. 15A is a schematic plan view illustrating the configuration of a junction barrier Schottky diode 14 to a fourteenth embodiment of the present according disclosure. FIG. 15B is a schematic cross-sectional view taken along the line A-A in FIG. 15A.

As illustrated in FIGS. 15A and 15B, the junction barrier Schottky diode 14 according to the fourteenth embodiment differs from the junction barrier Schottky diode 12 according to the twelfth embodiment in that the inner wall of the outer peripheral trench 63 is covered with the insulating film 70 made of HfO₂ or the like and that the outer peripheral trench 63 is filled with the anode electrode 40 with the insulating film 70 interposed therebetween. Other basic configurations are the same as those of the junction barrier Schottky diode 12 according to the twelfth embodiment, so the same reference numerals are given to the same elements, and overlapping description will be omitted. In the present embodiment as well, the backward withstand voltage can be further increased as in the twelfth embodiment.

### Fifteenth Embodiment

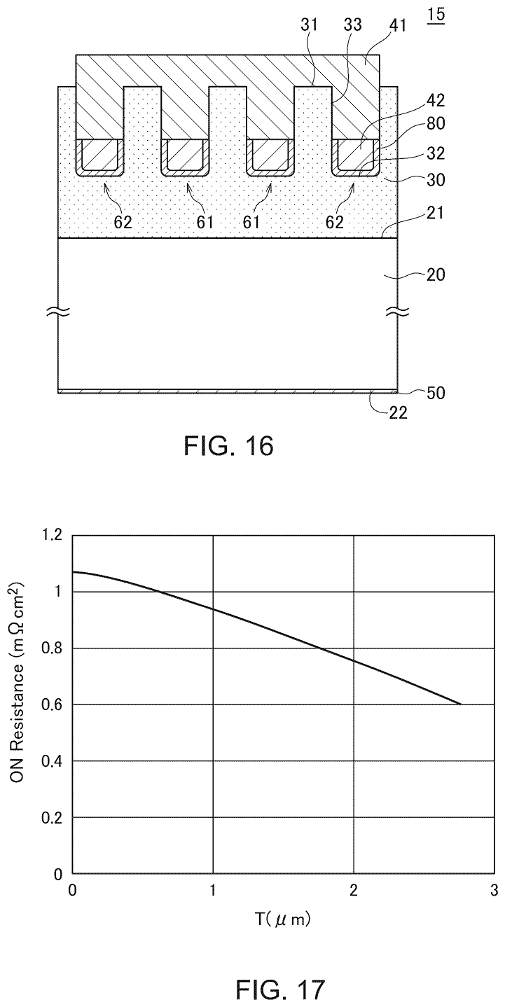

FIG. 16 is a schematic cross-sectional view illustrating the configuration of a junction barrier Schottky diode 15 according to a fifteenth embodiment of the present disclosure.

As illustrated in FIG. 16, the junction barrier Schottky diode 15 according to the fifteenth embodiment differs from the junction barrier Schottky diode 2 according to the second embodiment in that the anode electrode 41 brought into Schottky contact with the drift layer 30 is formed of a Cu single-layer film or a laminated film of Cu and Al and that the anode electrode 42 brought into ohmic contact with the p-type semiconductor material 80 is made of Ni. Other basic configurations are the same as those of the junction barrier Schottky diode 2 according to the second embodiment, so the same reference numerals are given to the same elements, and overlapping description will be omitted. By thus using a material different from that of the anode electrode 41 contacting the drift layer 30 as the material of the anode electrode 42 contacting the p-type semiconductor material 80, the p-type semiconductor material 80 and anode electrode 42 can be brought into ohmic contact with each other to reduce contact resistance therebetween. In one example, when the p-type semiconductor material 80 is NiO, using Ni for the anode electrode 42 allows the p-type semiconductor material 80 and anode electrode 42 to be brought into ohmic contact with each other. Alternatively, when the p-type semiconductor material 80 is a material having a band gap wider than that of NiO, the anode electrode 42 may be made of metal having a larger work function than that of Ni, such as Pt.

While the embodiment of the present disclosure has been described, the present disclosure is not limited to the above embodiment, and various modifications may be made within the scope of the present disclosure, and all such modifications are included in the present disclosure.

The technology according to the present disclosure includes the following configuration examples but not limited thereto.

A junction barrier Schottky diode according to the present disclosure includes: a semiconductor substrate made of gallium oxide; a drift layer made of gallium oxide and provided on the semiconductor substrate; an anode electrode brought into Schottky contact with the drift layer; and a cathode electrode brought into ohmic contact with the semiconductor substrate. The drift layer has a center trench filled with the anode electrode and a semiconductor material having a conductivity type opposite to that of the drift layer. The bottom surface of the center trench contacts the semiconductor material without being in contact with the anode electrode. At least a part of the side surface of the center trench is brought into Schottky contact with the anode electrode.

According to the present disclosure, the anode electrode filled in the center trench is brought into Schottky contact with the side surface of the center trench, thus making it possible to reduce the ON-resistance without increasing the impurity concentration of the drift layer.

In the present disclosure, the anode electrode may include a first anode electrode brought into Schottky contact with the upper surface of the drift layer and a second anode electrode brought into Schottky contact with the side surface of the center trench and made of a metal material different from that of the first anode electrode. This facilitates the manufacture of an anode electrode free from a void.

In the present disclosure, the drift layer may further have an outer peripheral trench surrounding the center trench. The bottom surface of the outer peripheral trench may contact the semiconductor material without being in contact with the anode electrode, and at least a part of the outer peripheral side surface of the outer peripheral trench may contact the semiconductor material. This relaxes an electric field generated at the outer peripheral bottom portion of the outer peripheral trench upon application of a backward voltage. In this case, at least a part of the inner peripheral side surface of the outer peripheral trench may be brought into Schottky contact with the anode electrode. This increases Schottky contact area to allow a further reduction in the ON-resistance.

In the present disclosure, the drift layer may further include an outer peripheral trench filled with the anode electrode and surrounding the center trench, and the inner wall of the outer peripheral trench may be covered with an insulating film without being in contact with the anode electrode. This relaxes an electric field generated at the outer peripheral bottom portion of the outer peripheral trench upon application of a backward voltage.

As described above, according to the present disclosure, the side surface of the center trench is brought into Schottky contact with the anode electrode, so that the ON-resistance of the junction barrier Schottky diode using oxide gallium can be reduced.

### EXAMPLES

### Example 1

A simulation model having the same structure as that of the junction barrier Schottky diode 1 illustrated in FIGS. 1A and 1B was assumed, and a resistance value was simulated with a forward voltage applied between the anode electrode 40 and the cathode electrode 50. The dopant concentration of the semiconductor substrate 20 was set to 1×10¹⁸ cm⁻³, and the dopant concentration of the drift layer 30 was to 3×10¹⁶ cm⁻³. The thickness of the drift layer 30 was set to 7 μm. The depths of the center and outer peripheral trenches 61 and 62 were both set to 3 μm. The width of the center and outer peripheral trenches 61 and 62 in the cross section illustrated in FIG. 1B and the width of the upper surface 31 of the drift layer 30 (i.e., the width of the mesa region M) were both set to 1.5 μm. The curvature radius of the curved surface 34 between the flat bottom surface 32 and the flat side surface 33 of each of the center and outer peripheral trenches 61 and 62 was set to 0.2 μm. As the p-type semiconductor material 80, NiO was used. The anode electrode 40 was made of Ni, and the cathode electrode 50 was formed of a laminated film of Ti and Au. Then, the simulation was performed using the depth T of the anode electrode 40 contacting the side surface 33 of each of the center and outer peripheral trenches 61 and 62 as a variable.

The simulation result was illustrated in FIG. 17. The graph of FIG. 17 revealed that the ON-resistance decreased with an increase in the depth T of the anode electrode 40 contacting the side surface 33 of each of the center and outer peripheral trenches 61 and 62. The backward withstand voltage was 7.8 MV/cm irrespective of the depth T.

What is claimed is:

1. A junction barrier Schottky diode comprising:
a semiconductor substrate made of gallium oxide;
a drift layer made of gallium oxide and provided on the semiconductor substrate;
an anode electrode brought into Schottky contact with the drift layer; and
a cathode electrode brought into ohmic contact with the semiconductor substrate,
wherein the drift layer has a center trench filled with the anode electrode and a semiconductor material having a conductivity type opposite to that of the drift layer,
wherein a bottom surface of the center trench contacts the semiconductor material without being in contact with the anode electrode, and
wherein at least a part of a side surface of the center trench is brought into Schottky contact with the anode electrode.

2. The junction barrier Schottky diode as claimed in claim 1, wherein the anode electrode includes a first anode electrode brought into Schottky contact with an upper surface of the drift layer and a second anode electrode brought into Schottky contact with the side surface of the center trench and made of a metal material different from that of the first anode electrode.

3. The junction barrier Schottky diode as claimed in claim 1,
wherein the drift layer further has an outer peripheral trench surrounding the center trench,
wherein a bottom surface of the outer peripheral trench contacts the semiconductor material without being in contact with the anode electrode, and
wherein at least a part of an outer peripheral side surface of the outer peripheral trench contacts the semiconductor material.

4. The junction barrier Schottky diode as claimed in claim 2,
wherein the drift layer further has an outer peripheral trench surrounding the center trench,
wherein a bottom surface of the outer peripheral trench contacts the semiconductor material without being in contact with the anode electrode, and
wherein at least a part of an outer peripheral side surface of the outer peripheral trench contacts the semiconductor material.

5. The junction barrier Schottky diode as claimed in claim 3, wherein at least a part of an inner peripheral side surface of the outer peripheral trench is brought into Schottky contact with the anode electrode.

6. The junction barrier Schottky diode as claimed in claim 4, wherein at least a part of an inner peripheral side surface of the outer peripheral trench is brought into Schottky contact with the anode electrode.

7. The junction barrier Schottky diode as claimed in claim 1,
wherein the drift layer further has an outer peripheral trench filled with the anode electrode and surrounding the center trench, and
wherein an inner wall of the outer peripheral trench is covered with an insulating film without being in contact with the anode electrode.

8. The junction barrier Schottky diode as claimed in claim 2,
wherein the drift layer further has an outer peripheral trench filled with the anode electrode and surrounding the center trench, and
wherein an inner wall of the outer peripheral trench is covered with an insulating film without being in contact with the anode electrode.
